(19) United States
(12) Patent Application Publication
(10) Pub. No.: US 2023/0245872 A1
(43) Pub. Date: Aug. 3, 2023

(54) Control of Processing Equipment

(71) Applicant: University of Exeter, Exeter (GB)

(72) Inventors: Gregory Austin Daly, Bristol (GB); Gavin Randal Tabor, Exeter (GB); Jonathan Edward Fieldsend, Exeter (GB)

(21) Appl. No.: 18/014,406

(22) PCT Filed: Jul. 7, 2021
(86) PCT No.: PCT/GB2021/051725

§ 371 Date: Jan. 4, 2023

(30) Foreign Application Priority Data
Jul. 8, 2020 (GB) 2010471.7

(51) Int. Cl. H01J 37/32; H01L 21/67; G05B 19/418

(52) U.S. Cl. CPC H01J 37/32926; H01J 37/3299; H01L 21/67069; G05B 19/41875; G05B 2219/32181

(57) ABSTRACT

Broadly speaking, the present techniques provide a method and system for controlling a wafer production process in real-time using a trained machine learning, ML, model. Advantageously, the ML model uses multiple sensed parameters to determine a state of a plasma used in the wafer production process, and this can be used to adjust at least one control parameter of a plasma reactor used in the wafer production process to reduce process variability.

### FIELD

The present techniques generally relate to controlling the operation of processing equipment, and in particular to the control of processing equipment for use in the production of wafers by plasma deposition and/or etching for use in, for example, micro- and nano-scale devices.

### BACKGROUND

Wafers are thin slices of semiconductors, that may typically be used to fabricate integrated circuits or manufacture solar cells. The wafers are often used as a substrate upon which micro- or nano-scale devices are built. Wafers are generally formed of a highly pure and, ideally, defect-free single crystalline material. In order to use the wafers for the above-mentioned purposes, they may need to undergo several fabrication processes, such as doping, ion implantation, etching, thin-film deposition and photolithography.

The processing of wafers for use in such applications is complex. Typically, plasma reactors are used for etching and/or deposition and, whilst it is desirable to be able to produce wafers of a consistent, reproducible form, the number of control parameters and variables involved in the processing of wafers in such arrangements is sufficiently high that this is difficult to achieve. As a result, there can be a significant amount of process variability in the processing of wafers. Process variability impacts, for example, the yields of integrated circuits (or “chips”) produced from semiconductors, the quality of such chips, and the types of chip design that can be manufactured. The processing variability may arise from variations in the processing chambers or plasma reactors, process drift over time, and process excursions (that may be caused by damaged equipment).

While wafers used in the electronics industry are typically formed of silicon, compound semiconductors wafers may be used for other purposes such as LED manufacturing. Compound semiconductors wafers may be from, for example, Gallium arsenide, Gallium nitride, or silicon carbide. The use of compound semiconductor wafers may give rise to particular issues. For example, some wafers may be formed of a two materials, where one semiconductor material is grown on top of another semiconductor material (e.g. Gallium nitride on silicon). In this case, the interface or interface layer between the two semiconductor materials may cause issues such as device stability problems, particularly when such wafers are used for photonic or quantum devices. It is desirable to have good control over refractive index and surface roughness because this impacts the performance or stability of such devices. Therefore, it is necessary to have good control over the processing techniques used to form the compound semiconductor wafers.

In order to be able to control the processing techniques, it is generally useful to be able to obtain some feedback on the processing to determine whether the processing is being performed as expected/required. Therefore, it may be useful to measure, for example, the state of the plasma, the condition of the plasma reactor or chamber, and the state of the wafer. However, the plasmas used to produce wafers are highly chemically reactive and interact with anything in the plasma chamber, including any dirt or residues within the plasma chamber, and any probe that may be used to measure the state of the plasma. The interaction causes the plasma to change, which thereby impacts the wafer production. It is therefore desirable to have non-invasive techniques to measure the state of the plasma. However, existing non-invasive techniques do not provide specific desired information, such as plasma density.

Existing control strategies are typically open loop strategies in which, after production of a batch of wafers, analysis of the batch can be used to derive information that may be used to adjust certain control parameters for use when the next batch of wafers is to be processed. In this manner, process variations and drift can be accounted for. Usually, batches of wafers comprise one designated metrology wafer, which is used to check the production process at each stage or at particular stages in the process. Wafer metrology may be able to specifically identify surface particles, pattern flaws and other issues that could adversely affect the performance of devices that use the wafers. Typically, the analysis takes the form of a quick check on the metrology wafer in a batch at each stage to check that it is worthwhile continuing processing, or whether the batch should be scrapped, and a more detailed metrology analysis that is used to ascertain control adjustments to affect the processing of later batches. The more detailed analysis is time consuming and so, in order to avoid production delays, processing may continue whilst the more detailed analysis is undertaken. By way of example, therefore, the result of the more detailed metrology analysis of the first batch may only be available to make adjustments for the processing of, say, the fourth or fifth batch. The analysis may reveal that the subsequently processed batches are not of a sufficiently good quality to be used, and so this processing methodology can lead to relatively high levels of waste through issues being identified too late in the process to allow appropriate corrective action to be taken. The approach is time consuming, costly and, as mentioned above, can be wasteful.

In an attempt to mitigate the disadvantages of the approach set out hereinbefore, arrangements are known in which ‘virtual metrology’ models are used to predict, based upon lower cost and quicker non-invasive diagnostic approaches, the outputs which would be achieved by conducting a full analysis of the processed wafer, and to use the modelled outputs in making adjustments to the control of the processing of future batches. Whilst this approach has the benefit that cost savings can be made, and the analysis approach may be less time consuming to undertake, future production quality is dependent upon the accuracy of the model used, and the models have typically been of a very basic form. In particular, typically simple analysis is done on non-invasive diagnostic data, such as optical emission spectroscopy, by extracting simple features, such as the ratio of the intensity of two emission lines, and using these as the input to the model, and as variations in this parameter may arise from a number of causes, there is a risk that the model output alone may be insufficient to allow appropriate corrective action to be taken.

The present applicant has therefore identified the need for a control method for use in the control of processing equipment whereby at least some of the disadvantages associated with known arrangements are overcome or are of reduced effect.

### SUMMARY

In a first approach of the present techniques, there is provided a computer-implemented method for controlling a wafer production process in real-time using a trained machine learning, ML, model, the method comprising: receiving sensor data from a plurality of sensors monitoring the wafer production process in real-time; inputting the sensor data from the plurality of sensors into a neural network of the trained ML model; generating, using the trained ML model, a latent representation of a state of a plasma used in the wafer production process; and adjusting in real-time, using the generated latent representation, at least one control parameter of a plasma reactor used in the wafer production process.

The processing characteristics monitored by the sensors may include, for example, RF power, temperature, pressure, gas flow rate, and characteristics such as electron density, the appearance of the wafer as detected by an optical camera, and optical emission spectroscopy outputs. However, the invention is not restricted to these specific characteristics and parameters, and sensors sensitive to other characteristics and parameters may be used, if desired.

At least some of the sensor information may be of highly complex form. By way of example, it may include data rich sources such as optical emissions spectroscopy outputs or optical images, as mentioned above.

Thus, the step of receiving sensor data may comprise receiving: at least one image of the plasma used in the wafer production process, and at least one optical emission spectrograph of the plasma.

Additionally or alternatively, the step of receiving sensor data may comprise receiving at least one of: RF power applied to the plasma reactor, temperature inside the plasma reactor, pressure inside the plasma reactor, gas flow rate into the plasma reactor, plasma impedance, and plasma electron density.

The step of generating a latent representation of a state of a plasma used in the wafer production process may comprise: combining, using the neural network, the sensor data to generate a latent representation in real-time of the state of the plasma.

The machine learning model may be an unsupervised machine learning or deep learning model. The neural network of the machine learning model may comprise an autoencoder. The autoencoder may be operable to merge a plurality of sensor outputs into a single meaningful representation, and to extract from that representation outputs (or adjusted inputs) suitable for use in adjusting control parameters of the processing equipment. It will be appreciated that, in this manner, a large number of characteristics can be taken into account in controlling the processing equipment, and that the control parameters of the equipment can be adjusted substantially in real time, allowing a good level of control over product uniformity and consistency, and a reduction in waste, whilst maintaining a high production speed. In this manner, production may be undertaken quickly and efficiently.

The method may further comprise: comparing the generated latent representation of the state of the plasma with a desired latent representation of an ideal state of the plasma; and identifying any difference between the generated and desired latent representations.

The comparing and identifying steps may be performed as follows. The generated latent representation may be 256 floats. This fact may be used to calculate the overall Euclidean difference between the desired and generated latent representations, as a single scalar or a matrix of Euclidean distance between each value in the latent representations. The scalar or matrix could then be fed into a reinforcement learning module of the ML model. The Euclidean distance would also be used in training the reinforcement learning module as part of a reward function.

Alternatively, the comparing and identifying steps may be performed as follows. The generated and desired latent representations may be fed into a reinforcement learning module of the ML model, which learns to determine the difference between the two representations. The Euclidean distance calculation may only be used in calculating a reward function of the reinforcement learning module for training the model.

The desired latent representation may be a single latent representation that should be maintained over the whole process, or may be one of a series or set of latent representations, where different latent representations may be desired at different stages of the process. Thus, the comparison may comprise selecting the appropriate desired latent representation to compare with the generated latent representation. The desired latent representation(s) may be determined or learned by the training of the machine learning model.

Preferably, adjusting at least one control parameter of a plasma reactor used in the wafer production process may comprise: determining at least one parameter of the wafer production process to adjust to minimise any identified difference between the generated latent representation and the desired latent representation; and adjusting the determined at least one parameter. The determining may be performed by the ML model, such as for example, by the reinforcement learning module. The module may output at least one parameter to be adjusted by the next time step.

The method may further comprise: outputting an alert to an operator of the plasma reactor when the identified difference between the generated and latent representations exceeds a threshold value or cannot be minimised by adjusting at least one parameter.

Combining the sensor data (using for example, the autoencoder) may comprise combining sensor data having different spatial and/or temporal dimensionality. Certain autoencoder inputs may themselves be the output from neural networks or the like.

An example technique for combining the sensor data is described, where the sensor data is spectral data and image data. The image data may be an RGB image that has low spectral resolution and high spatial resolution. The spectral data may be a spectra that is a spatial average with high spectral resolution. A convolutional encoder of the ML model may branch to learn to extract features from each data item separately, and a deep encoder of the ML model may learn to combine the extracted features.

For different temporal resolution data, two techniques may be used to combine the data. For example, if the input sensor data is obtained from an in-situ wafer metrology method/sensor that provides the average etch or deposition rate over tens of seconds (such as what may be obtained from a full wafer interferometer), the data could be combined with all the spectra collected over that time by first passing the time averaged metrology data through its own branch in the ML model to the deep encoder, and then applying one of the following techniques. One technique comprises passing each spectra through the convolutional branch to extract features, passing those features through a time series network like a long short-term memory (LSTM) network, and then passing the output of the LSTM network to the deep encoder. Another technique comprises stacking the optical emission spectra together to create a 2D spectrograph and passing this through a branch, similar to the image branch, to the deep encoder. Both of these techniques work similarly in higher or lower dimensions.

In a second approach of the present techniques, there is provided a computer-implemented method for training a machine learning, ML, model for controlling a wafer production process in real-time, the method comprising: receiving training data comprising sensor data from a plurality of sensors monitoring a wafer production process; inputting the training data into a neural network of the ML model; and training the neural network of the ML model to generate a latent representation of a state of a plasma in a plasma reactor used in the wafer production process.

Receiving training data may comprise receiving a plurality of sets of data items, wherein each set of data items comprises an image of the plasma and an optical emission spectrograph of the plasma, and wherein for each set of data items the data items are collected at the same point in time.

Each set of data items may further comprise at least one of: RF power applied to the plasma reactor, temperature of chamber furniture inside the plasma reactor, pressure inside the plasma reactor, gas flow rate into the plasma reactor, plasma impedance, and plasma electron density.

Training the neural network may comprise training an encoder of the neural network to: combine each set of data items to generate a latent representation of the state of the plasma at a particular point in time.

Training the neural network may further comprise training a decoder of the neural network to: reconstruct, from the generated latent representation, a set of data items corresponding to the generated latent representation; and minimise, using backpropagation, a difference between the set of data items and the reconstructed set of data items.

Training the neural network may further comprise: inputting, into the neural network, a desired latent representation of an ideal state of the plasma; training the neural network to identify any difference between each generated latent representation and the desired latent representation; and determining at least one parameter of the wafer production process to adjust to minimise any identified difference between each generated latent representation and the desired latent representation. The determining may be performed by the ML model, such as for example, by a reinforcement learning agent/module. The module may output at least one parameter to be adjusted by the next time step.

In a third approach of the present techniques, there is provided a system for wafer production, the system comprising: a plasma reactor; a plurality of sensors for monitoring a wafer production process; and a control unit, comprising at least one processor coupled to memory and comprising a trained machine learning, ML, model, wherein the control unit is arranged to: receive, in real-time, sensor data from the plurality of sensors monitoring the wafer production process; input the sensor data from the plurality of sensors into a neural network of the trained ML model; generate, using the trained ML model, a latent representation of a state of a plasma used in the wafer production process; and adjust in real-time, using the generated latent representation, at least one control parameter of a plasma reactor used in the wafer production process.

Features described above with respect to the first approach apply equally to the third approach.

The plurality of sensors may comprise any one or more of: a temperature sensor, a pressure sensor, an imaging device, in situ wafer metrology equipment, a spectrometer, optical emission spectroscopy equipment, a radio-frequency sensor, a photodiode, a microwave probe, a flow rate sensor.

In a related approach of the present techniques, there is provided a non-transitory data carrier carrying processor control code to implement any of the methods, processes and techniques described herein.

As will be appreciated by one skilled in the art, the present techniques may be embodied as a system, method or computer program product. Accordingly, present techniques may take the form of an entirely hardware embodiment, an entirely software embodiment, or an embodiment combining software and hardware aspects.

Furthermore, the present techniques may take the form of a computer program product embodied in a computer readable medium having computer readable program code embodied thereon. The computer readable medium may be a computer readable signal medium or a computer readable storage medium. A computer readable medium may be, for example, but is not limited to, an electronic, magnetic, optical, electromagnetic, infrared, or semiconductor system, apparatus, or device, or any suitable combination of the foregoing.

Computer program code for carrying out operations of the present techniques may be written in any combination of one or more programming languages, including object oriented programming languages and conventional procedural programming languages. Code components may be embodied as procedures, methods or the like, and may comprise sub-components which may take the form of instructions or sequences of instructions at any of the levels of abstraction, from the direct machine instructions of a native instruction set to high-level compiled or interpreted language constructs.

Embodiments of the present techniques also provide a non-transitory data carrier carrying code which, when implemented on a processor, causes the processor to carry out any of the methods described herein.

The techniques further provide processor control code to implement the above-described methods, for example on a general purpose computer system or on a digital signal processor (DSP). The techniques also provide a carrier carrying processor control code to, when running, implement any of the above methods, in particular on a non-transitory data carrier. The code may be provided on a carrier such as a disk, a microprocessor, CD- or DVD-ROM, programmed memory such as non-volatile memory (e.g. Flash) or read-only memory (firmware), or on a data carrier such as an optical or electrical signal carrier. Code (and/or data) to implement embodiments of the techniques described herein may comprise source, object or executable code in a conventional programming language (interpreted or compiled) such as C, or assembly code, code for setting up or controlling an ASIC (Application Specific Integrated Circuit) or FPGA (Field Programmable Gate Array), or code for a hardware description language such as Verilog® or VHDL (Very high speed integrated circuit Hardware Description Language). As the skilled person will appreciate, such code and/or data may be distributed between a plurality of coupled components in communication with one another. The techniques may comprise a controller which includes a microprocessor, working memory and program memory coupled to one or more of the components of the system.

It will also be clear to one of skill in the art that all or part of a logical method according to embodiments of the present techniques may suitably be embodied in a logic apparatus comprising logic elements to perform the steps of the above-described methods, and that such logic elements may comprise components such as logic gates in, for example a programmable logic array or application-specific integrated circuit. Such a logic arrangement may further be embodied in enabling elements for temporarily or permanently establishing logic structures in such an array or circuit using, for example, a virtual hardware descriptor language, which may be stored and transmitted using fixed or transmittable carrier media.

In an embodiment, the present techniques may be implemented using multiple processors or control circuits. The present techniques may be adapted to run on, or integrated into, the operating system of an apparatus.

In an embodiment, the present techniques may be realised in the form of a data carrier having functional data thereon, said functional data comprising functional computer data structures to, when loaded into a computer system or network and operated upon thereby, enable said computer system to perform all the steps of the above-described method.

### BRIEF DESCRIPTION OF THE DRAWINGS

The invention will further be described, by way of example, with reference to the accompanying drawings, in which:

FIG. 1 is a schematic block diagram of a system for wafer production;

FIG. 2 is a flow chart illustrating example steps to control a wafer production process in real-time using a trained machine learning model;

FIG. 3 is a diagrammatic representation of part of the control arrangement;

FIG. 4A is a schematic diagram illustrating an example machine learning model for use in controlling a wafer production process in real-time;

FIG. 4B is a schematic diagram illustrating a further example machine learning model for use in controlling a wafer production process in real-time; and

FIG. 5 shows an experimental data sweep pattern used to collect data for training the machine learning model.

### DETAILED DESCRIPTION OF THE DRAWINGS

Broadly speaking, the present techniques provide a method and system for controlling a wafer production process in real-time using a trained machine learning, ML, model. Advantageously, the ML model uses multiple sensed parameters to determine a state of a plasma used in the wafer production process, and this can be used to adjust at least one control parameter of a plasma reactor used in the wafer production process to reduce process variability.

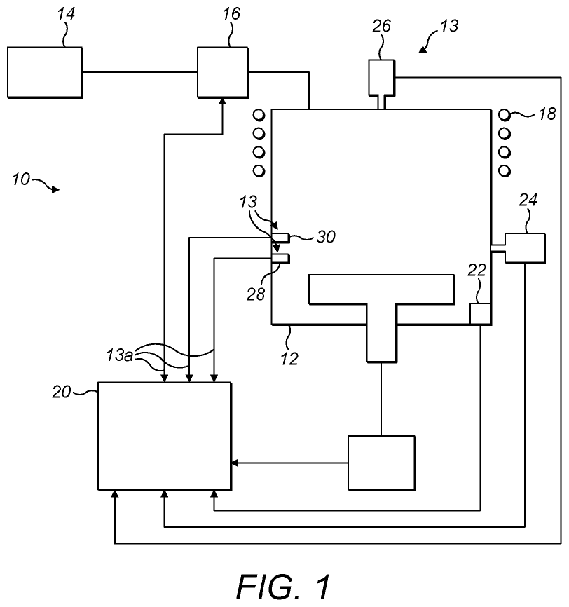

FIG. 1 is a schematic block diagram of a system 10 for wafer production (also referred to herein as “wafer processing equipment”). The system 10 comprises a processing chamber or plasma reactor 12 within which a wafer to be processed is located, in use. The terms “processing chamber” and “plasma reactor” are used interchangeably herein. A process gas is supplied to the processing chamber 12 from a source 14. A control metering and valve arrangement 16 is operable to control and monitor the rate at which the process gas is supplied to the processing chamber 12. An excitation coil 18 surrounds the processing chamber 12. It will be appreciated that by applying a suitable varying signal to the excitation coil 18, whilst delivering controlled pulses of the process gas to the processing chamber 12, plasma etching of the wafer located within the processing chamber 12 or plasma deposition may be achieved in a controlled manner. Plasma etching and/or deposition in this manner is well known and so is not described herein in further detail.

The system 10 may comprise a number of sensors 13 associated with the processing chamber 12. Outputs 13A of the sensors are supplied to a control unit 20, for example in the form of a suitably programmed computer. Whilst a suitably programmed computer is described as constituting the control unit 20, it will be appreciated the control unit 20 could take other forms, and may comprise a device specifically designed for use in the control of the processing equipment 10. The control unit 20 may comprise at least one processor coupled to memory. The at least one processor may comprise one or more of: a microprocessor, a microcontroller, and an integrated circuit. The memory may comprise volatile memory, such as random access memory (RAM), for use as temporary memory, and/or non-volatile memory such as Flash, read only memory (ROM), or electrically erasable programmable ROM (EEPROM), for storing data, programs, or instructions, for example.

The sensors are sensitive to a number of parameters associated with this processing chamber 12. The sensors 13 may comprise any one or more of: temperature and pressure sensors 22 sensitive to temperature and pressure conditions within the processing chamber 12, an optical camera 24 positioned to allow monitoring of the appearance of the wafer, in situ wafer metrology equipment 26, a spectrometer 28, and other optical monitors or sensors 30. In addition, the control unit 20 is supplied with flow rate information from the process gas control metering and valve arrangement 16, and impedance, phase and voltage information.

The sensors 13 may comprise a number of sensors for measuring properties of the plasma. The sensors may comprise an imaging device (e.g. camera or RGB camera) for imaging the plasma within the processing chamber 12, optical emission spectrography equipment, radio-frequency sensors, a photodiode, and/or microwave probes.

The sensors 13 may comprise one or more in-situ metrology sensors for determining properties of the designated metrology wafer in a batch of wafers. The metrology sensor may be a full wafer interferometer and/or a spectral reflectometer.

The sensors 13 may comprise one or more sensors for measuring properties of the processing chamber, such as pressure, voltage, temperature, and so on.

Preferably, to generate an accurate latent representation of the plasma at a given point in time, the sensor data is collected simultaneously from multiple sensors. Sensor data may be collected at regular time intervals, or after particular processing steps have been performed, for example.

It will be appreciated that some of the sensor outputs 13a such as temperature and pressure may be of relatively simple form, but that others such as spectrometer outputs and optical camera outputs may be of highly complex, data rich form.

The control unit 20 is operable, as described below, to control the control parameters of the processing equipment 10, such as the operation of the coil 18 and the control metering and valve arrangement 16 (and if desired, other control parameters associated with the processing equipment 10) in response to the received sensor information as set out below.

Thus, system 10 comprises: a plasma reactor 12; a plurality of sensors 13 for monitoring a wafer production process; and a control unit 20, comprising at least one processor coupled to memory. The control unit 20 further comprises a trained machine learning, ML, model, (not shown). The control unit 20 is arranged to: receive, in real-time, sensor data from the plurality of sensors 13 monitoring the wafer production process; input the sensor data from the plurality of sensors into a neural network of the trained ML model; generate, using the trained ML model, a latent representation of a state of a plasma used in the wafer production process; and adjust in real-time, using the generated latent representation, at least one control parameter of the plasma reactor 12 used in the wafer production process.

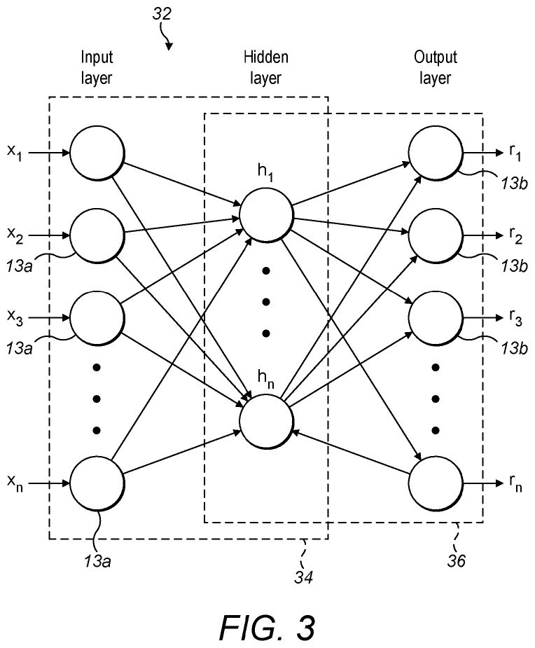

As shown in FIG. 3, the machine learning model of the control unit 20 may be an unsupervised machine learning model or deep learning model. The neural network of the ML model may comprise an autoencoder 32 defining an encoder 34 in which the various sensor outputs 13a are combined with one another to form a single meaningful representation (i.e. the latent representation of the state of the plasma) which can be compared with an ideal, desired or target representation, and a decoder 36. The decoder 36 tries to reconstruct the inputs from the generated latent representation during training of the ML model. The decoder is therefore used to reduce an error between the reconstructed inputs and the original input data used to generate the latent representation, as part of the model training process. After the ML model has been trained, the control unit 20 uses the generated latent representation produced by the encoder 34 to control or adjust the control parameters of the processing equipment, such as the gas flow rate as controlled by the control metering and valve arrangement 16. In this manner, it will be appreciated that wafer processing can be controlled, substantially in real time, to compensate for variations in the manner in which the equipment is operating and variations in the wafers being processed, to achieve a good level of product uniformity and to reduce the level of waste produced through the control equipment producing products of unacceptable quality.

The autoencoder may combine the sensor outputs in any suitable manner, and so data with different temporal or spatial dimensionality may be combined, if desired.

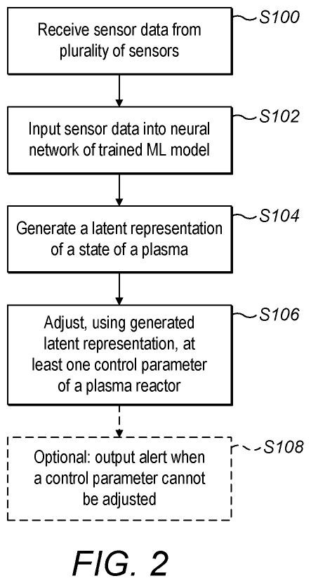

FIG. 2 is a flow chart illustrating example steps to control a wafer production process in real-time using a trained machine learning model. The computer-implemented method comprises: receiving sensor data from a plurality of sensors monitoring the wafer production process in real-time (step S100). Receiving sensor data may comprise receiving: at least one image of the plasma used in the wafer production process, and at least one optical emission spectrograph of the plasma. Additionally or alternatively, the step of receiving sensor data may comprise receiving at least one of: RF power applied to the plasma reactor, temperature inside the plasma reactor, pressure inside the plasma reactor, gas flow rate into the plasma reactor, plasma impedance, and plasma electron density.

The method may comprise inputting the sensor data from the plurality of sensors into a neural network of the trained ML model (step S102).

The method may comprise generating, using the trained ML model, a latent representation of a state of a plasma used in the wafer production process (step S104). The step of generating a latent representation of a state of a plasma used in the wafer production process may comprise: combining, using the neural network, the sensor data to generate a latent representation in real-time of the state of the plasma.

The method may further comprise: comparing the generated latent representation of the state of the plasma with a desired latent representation of an ideal state of the plasma; and identifying any difference between the generated and latent representations.

The method may comprise adjusting in real-time, using the generated latent representation, at least one control parameter of a plasma reactor used in the wafer production process (step S106). Preferably, adjusting at least one control parameter of a plasma reactor used in the wafer production process may comprise: determining at least one parameter of the wafer production process to adjust to minimise any identified difference between the generated latent representation and the desired latent representation; and adjusting the determined at least one parameter.

Optionally, the method may further comprise: outputting an alert to an operator of the plasma reactor when the identified difference between the generated and latent representations exceeds a threshold value or cannot be minimised by adjusting at least one parameter (step S108).

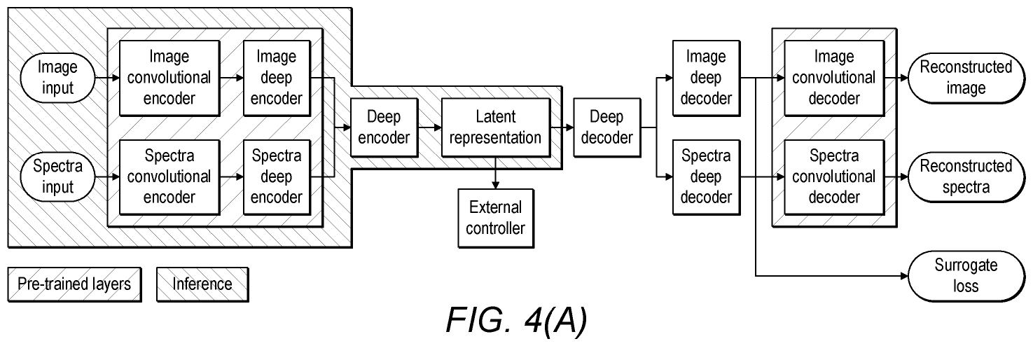

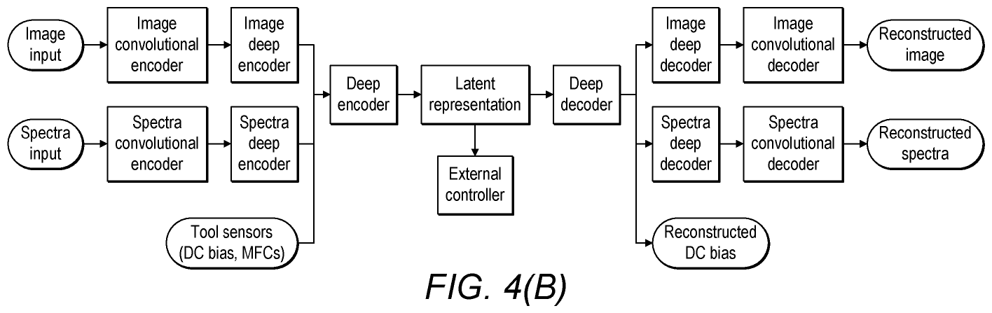

FIG. 4A is a schematic diagram illustrating an example machine learning model for use in controlling a wafer production process in real-time. In this example, images and spectra (e.g. optical emission spectra) are input into the model to determine the latent representation of the state of the plasma, both during training of the model and during inference. Only the left-hand side of the model is used during inference (i.e. during run-time). The left-hand side shows an encoder portion of the neural network of the ML model, which is used to generate the latent representation. The right-hand side shows a decoder portion of the neural network, which is used during training of the model.

A computer-implemented method for training a machine learning, ML, model for controlling a wafer production process in real-time, may comprise: receiving training data comprising sensor data from a plurality of sensors monitoring a wafer production process; inputting the training data into a neural network of the ML model; and training the neural network of the ML model to generate a latent representation of a state of a plasma in a plasma reactor used in the wafer production process.

As shown in FIG. 4A, receiving training data may comprise receiving a plurality of sets of data items, wherein each set of data items comprises an image of the plasma and an optical emission spectrograph of the plasma. For each set of data items the data items are collected at the same point in time. This enables a more accurate representation of the state of a plasma at a given point in time to be generated.

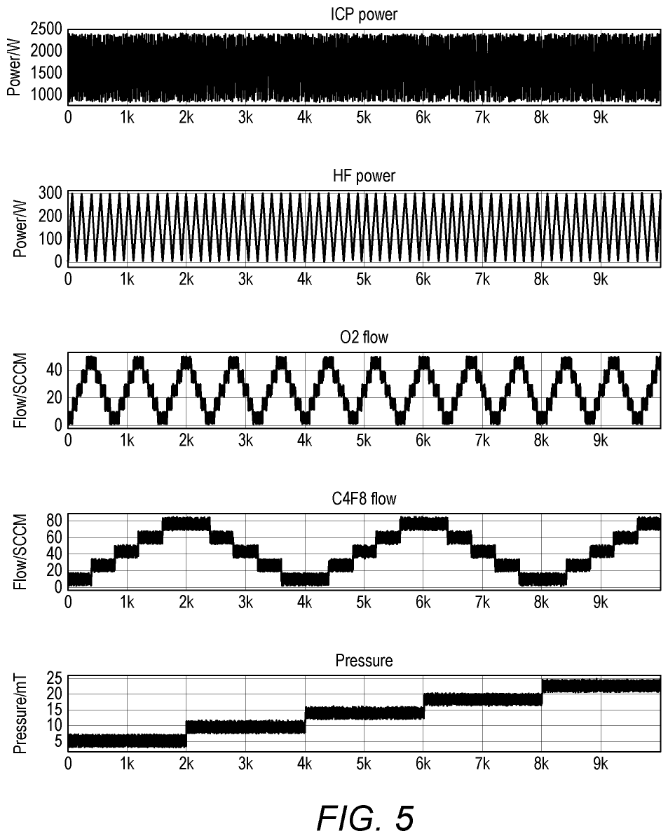

Collecting data from the sensors to form the training data may comprise running the system 10 for many days using different plasma conditions in order to collect hundreds of thousands of data points. In particular, image and spectra pairs at a plurality of time points may be collected. The different plasma conditions represent samples of conditions across a parameter space with high dimensionality (2 electrode powers, pressure, 3 temperatures (table, wall, liners), 6-10 process gasses with many possible mixtures). FIG. 5 shows an experimental data sweep pattern used to collect data for training the machine learning model. A Sobol sequence may be used to generate a quasi-random sequence of data points to sample across the space efficiently and then sweep across the parameter space (as per the sweep plot shown in FIG. 5) to collect data. The sweep may be performed every 8 seconds, for example, where the parameters are changed at the same frequency.

FIG. 4A shows the connections in the autoencoder. It has been found that training the whole model simultaneously does not work, because one branch may train and dominate all other parts and branches of the model. Therefore, it has been determined that each sensor branch in FIG. 4A may need to be trained individually. Neural network weights determined after each sensor branch has been trained may then be transferred to the complete autoencoder.

As shown in FIG. 4A, each input sensor data is first dealt with separately by the encoder of the ML model. For example, the image data may be an RGB image that has low spectral resolution and high spatial resolution, and the spectral data may be a spectra that is a spatial average with high spectral resolution. A convolutional encoder of the ML model may branch to learn to extract features from each data item separately, as shown by the branches in FIG. 4A, and a deep encoder of the ML model may learn to combine the extracted features. Any suitable techniques may be used to perform feature extraction.

For different temporal resolution data, two techniques may be used to combine the data. For example, if the input sensor data is obtained from an in-situ wafer metrology method/sensor that provides the average etch or deposition rate over tens of seconds (such as what may be obtained from a full wafer interferometer), the data could be combined with all the spectra collected over that time by first passing the time averaged metrology data through its own branch in the ML model to the deep encoder, and then applying one of the following techniques. One technique comprises passing each spectra through the convolutional branch to extract features, passing those features through a time series network like a long short-term memory (LSTM) network, and then passing the output of the LSTM network to the deep encoder. Another technique comprises stacking the optical emission spectra together to create a 2D spectrograph and passing this through a branch, similar to the image branch, to the deep encoder. Both of these techniques work similarly in higher or lower dimensions.

A Root Mean Squared Error of the output of the sensor deep decoder in the whole encoder is calculated and compared to the same output on the individual pre-trained individual sensor encoder. This helps to guide the neural network to form a similar representation from each sensor while training, but allows the deep encoder, latent representation and deep decoder enough freedom in training to find a good representation that gets to an overall lower loss.

FIG. 4B is a schematic diagram illustrating a further example machine learning model for use in controlling a wafer production process in real-time. This shows how additional sensor data may be used to generate the latent representation, both during training and inference. Therefore, each set of data items used to train the model (and at inference time) may further comprise at least one of: RF power applied to the plasma reactor, temperature inside the plasma reactor, pressure inside the plasma reactor, gas flow rate into the plasma reactor, plasma impedance, and plasma electron density.

It can be seen from FIGS. 4A and 4B that training the neural network may comprise training an encoder of the neural network to: combine each set of data items to generate a latent representation of the state of the plasma at a particular point in time.

Similarly, FIGS. 4A and 4B show how training the neural network may further comprise training a decoder of the neural network to: reconstruct, from the generated latent representation, a set of data items corresponding to the generated latent representation; and minimise, using backpropagation, a difference between the set of data items and the reconstructed set of data items.

Training the neural network may further comprise: inputting, into the neural network, a desired latent representation of an ideal state of the plasma; training the neural network to identify any difference between each generated latent representation and the desired latent representation; and determining at least one parameter of the wafer production process to adjust to minimise any identified difference between each generated latent representation and the desired latent representation.

The comparison of the single meaningful representation with the target representation is preferably undertaken using a reinforcement learning technique in which a reinforcement learning agent/module receives a continuous reward signal indicative of a difference between the single meaningful representation and a target representation and, whilst training, learns how adjustments to the control parameters impacts upon the rewards signal. Once trained, the reinforcement learning agent exploits its knowledge to maintain the processing equipment in a stable condition in which the products produced thereby are at an acceptable level of quality. During production, the reward signal can still be used to achieve additional training, and adjustments made to the control parameters to adjust for slow changes in behaviour. If sudden changes in behaviour are noted, identified by a sudden change in the reward signal, the operator may be notified and the processing equipment 10 shut down.

It will be appreciated that, in accordance with the invention, a large number of sensor outputs may be used, substantially in real time, in controlling the operation of the processing equipment. Accordingly, variations in processing of the wafers may be quickly addressed, leading to enhanced product uniformity. Closed loop control, using the outputs of a number of sensors sensitive to a wide range of parameters or characteristics may be achieved.

Further example embodiments and features are described in the numbered paragraphs below:

Example 1: A control method for use in controlling the processing equipment used in the processing of a wafer, the method comprising receiving sensor information from a plurality of sensors sensitive to product and/or processing characteristics, inputting the sensor information into an unsupervised machine learning or deep learning model, and using the output of the model, substantially in real time, in adjusting at least one control parameter of the processing equipment.

Example 2: The method of Example 1, wherein the processing characteristics monitored by the sensors include at least one of RF power, temperature, pressure, gas flow rate, and characteristics such as electron density, the appearance of the wafer as detected by an optical camera, and optical emission spectroscopy outputs.

Example 3: The method of Example 1, wherein the unsupervised machine learning or deep learning model comprises a neural network.

Example 4: The method of Example 3, wherein the neural network includes an autoencoder operable to merge a plurality of sensor outputs into a single meaningful representation, and to extract from that representation outputs (or adjusted inputs) suitable for use in adjusting control parameters of the processing equipment.

Example 5: The method of Example 4, wherein the autoencoder combines data with different spatial and/or temporal dimensionality.

Example 6: The method of Example 4 or Example 5, wherein certain of the autoencoder inputs are themselves the outputs from neural networks or the like.

Example 7: Processing equipment comprising a processing chamber, a plurality of sensors sensitive to product and/or processing characteristics, a control unit to which sensor information from the sensors is supplied, the control unit comprising an unsupervised machine learning or deep learning model operable to produce an output which, substantially in real time, is used to control at least one control parameter of the processing equipment.

Those skilled in the art will appreciate that while the foregoing has described what is considered to be the best mode and where appropriate other modes of performing present techniques, the present techniques should not be limited to the specific configurations and methods disclosed in this description of the preferred embodiment. Those skilled in the art will recognise that present techniques have a broad range of applications, and that the embodiments may take a wide range of modifications without departing from any inventive concept as defined in the appended claims.

1-18. (canceled)

19. A computer-implemented method for controlling a wafer production process in real-time using a trained machine learning, ML, model, the method comprising:
receiving sensor data from a plurality of sensors monitoring the wafer production process in real-time;
inputting the sensor data from the plurality of sensors into a neural network of the trained ML model;
generating, using the trained ML model, a latent representation of a state of a plasma used in the wafer production process; and
adjusting in real-time, using the generated latent representation, at least one control parameter of a plasma reactor used in the wafer production process.

20. The method as claimed in claim 19, wherein receiving sensor data comprises receiving:
at least one image of the plasma used in the wafer production process, and
at least one optical emission spectrograph of the plasma.

21. The method as claimed in claim 19, wherein receiving sensor data comprises receiving at least one of: RF power applied to the plasma reactor, temperature of chamber furniture inside the plasma reactor, pressure inside the plasma reactor, gas flow rate into the plasma reactor, plasma impedance, and plasma electron density.

22. The method as claimed in claim 19 wherein generating a latent representation of a state of a plasma used in the wafer production process comprises:
combining, using the neural network, the sensor data to generate a latent representation in real-time of the state of the plasma.

23. The method as claimed in claim 19 wherein the neural network comprises an autoencoder.

24. The method as claimed in claim 19 further comprising:
comparing the generated latent representation of the state of the plasma with a desired latent representation of an ideal state of the plasma; and
identifying any difference between the generated and desired latent representations.

25. The method as claimed in claim 24 wherein adjusting at least one control parameter of a plasma reactor used in the wafer production process comprises:
determining at least one parameter of the wafer production process to adjust to minimize any identified difference between the generated latent representation and the desired latent representation; and
adjusting the determined at least one parameter.

26. The method as claimed in claim 24 further comprising:
outputting an alert to an operator of the plasma reactor when the identified difference between the generated and latent representations exceeds a threshold value or cannot be minimized by adjusting at least one parameter.

27. The method as claimed in claim 22, wherein combining the sensor data comprises combining sensor data having different spatial and/or temporal dimensionality.

28. A computer-implemented method for training a machine learning, ML, model for controlling a wafer production process in real-time, the method comprising:
receiving training data comprising sensor data from a plurality of sensors monitoring a wafer production process;
inputting the training data into a neural network of the ML model; and
training the neural network of the ML model to generate a latent representation of a state of a plasma in a plasma reactor used in the wafer production process.

29. The method as claimed in claim 28 wherein receiving training data comprises receiving a plurality of sets of data items, wherein each set of data items comprises an image of the plasma and an optical emission spectrograph of the plasma, and wherein for each set of data items the data items are collected at the same point in time.

30. The method as claimed in claim 29 wherein each set of data items further comprises at least one of: RF power applied to the plasma reactor, temperature inside the plasma reactor, pressure inside the plasma reactor, gas flow rate into the plasma reactor, plasma impedance, and plasma electron density.

31. The method as claimed in claim 29 wherein training the neural network comprises training an encoder of the neural network to:
combine each set of data items to generate a latent representation of the state of the plasma at a particular point in time.

32. The method as claimed in claim 31 wherein training the neural network further comprises training a decoder of the neural network to:
reconstruct, from the generated latent representation, a set of data items corresponding to the generated latent representation; and
minimize, using backpropagation, a difference between the set of data items and the reconstructed set of data items.

33. The method as claimed in claim 28 wherein training the neural network further comprises:
inputting, into the neural network, a desired latent representation of an ideal state of the plasma;
training the neural network to identify any difference between each generated latent representation and the desired latent representation; and
determining at least one parameter of the wafer production process to adjust to minimize any identified difference between each generated latent representation and the desired latent representation.

34. A system for wafer production, the system comprising:
a plasma reactor;
a plurality of sensors for monitoring a wafer production process; and
a control unit, comprising at least one processor coupled to memory and comprising a trained machine learning, ML, model, wherein the control unit is arranged to:
receive, in real-time, sensor data from the plurality of sensors monitoring the wafer production process;
input the sensor data from the plurality of sensors into a neural network of the trained ML model;
generate, using the trained ML model, a latent representation of a state of a plasma used in the wafer production process; and
adjust in real-time, using the generated latent representation, at least one control parameter of a plasma reactor used in the wafer production process.

35. The system as claimed in claim 34 wherein the plurality of sensors comprises any one or more of: a temperature sensor, a pressure sensor, an imaging device, in situ wafer metrology equipment, a spectrometer, optical emission spectroscopy equipment, a radio-frequency sensor, a photodiode, a microwave probe, a flow rate sensor.
